(19) United States
(12) Patent Application Publication
(10) Pub. No.: US 2023/0402366 A1
(43) Pub. Date: Dec. 14, 2023

(54) SEMICONDUCTOR DEVICE INCLUDING METAL SURROUNDING VIA CONTACT AND METHOD OF FORMING THE SEMICONDUCTOR DEVICE

(71) Applicant: TAIWAN SEMICONDUCTOR MANUFACTURING COMPANY, LTD., Hsinchu (TW)

(72) Inventors: Shuen-Shin LIANG, Hsinchu (TW); Chia-Hung CHU, Hsinchu (TW); Po-Chin CHANG, Hsinchu (TW); Hsu-Kai CHANG, Hsinchu (TW); Kuan-Kan HU, Hsinchu (TW); Ken-Yu CHANG, Hsinchu (TW); Hung-Yi HUANG, Hsinchu (TW); Harry CHIEN, Hsinchu (TW); Wei-Yip LOH, Hsinchu (TW); Chun-I TSAI, Hsinchu (TW); Hong-Mao LEE, Hsinchu (TW); Sung-Li WANG, Hsinchu (TW); Pinyen LIN, Hsinchu (TW); Chuan-Hui SHEN, Hsinchu (TW)

(73) Assignee: TAIWAN SEMICONDUCTOR MANUFACTURING COMPANY, LTD., Hsinchu (TW)

(21) Appl. No.: 17/836,781

(22) Filed: Jun. 9, 2022

(51) Int. Cl. H01L 23/522; H01L 23/532; H01L 21/768

(52) U.S. Cl. CPC H01L 23/5226; H01L 23/53266; H01L 21/76843; H01L 21/76883

(57) ABSTRACT

A semiconductor device includes a substrate, a source/drain region disposed in the substrate, a silicide structure disposed on the source/drain region, a first dielectric layer disposed over the substrate, a conductive contact disposed in the first dielectric layer and over the silicide structure, a second dielectric layer disposed over the first dielectric layer, a via contact disposed in the second dielectric layer and connected to the conductive contact, and a first metal surrounding the via contact.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. Therefore, it is desirable to continuously improve the structure and manufacturing of the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a method of making a semiconductor device in accordance with some embodiments.

FIGS. 2 to 6 and 8 to 10 show intermediate steps of a method of making a semiconductor device in accordance with some embodiments.

FIG. 7 is a graph plot illustrating the etch amount versus time of WO₃ and TiON by using WF₆ as an etchant, in accordance with some embodiments.

FIGS. 11 to 12 show intermediate steps of a method of making a semiconductor device in accordance with some embodiments.

FIGS. 13 to 18 show schematic partial views of semiconductor devices in accordance with some embodiments.

FIGS. 19 to 21 show intermediate steps of a method of making a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. In addition, the term “source/drain region(s)” may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

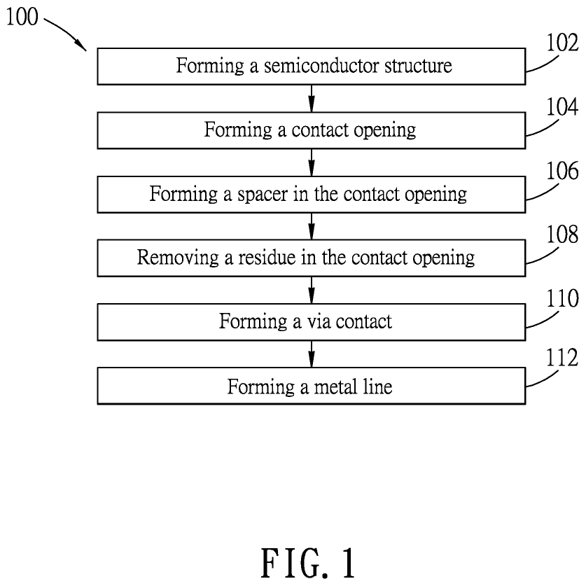

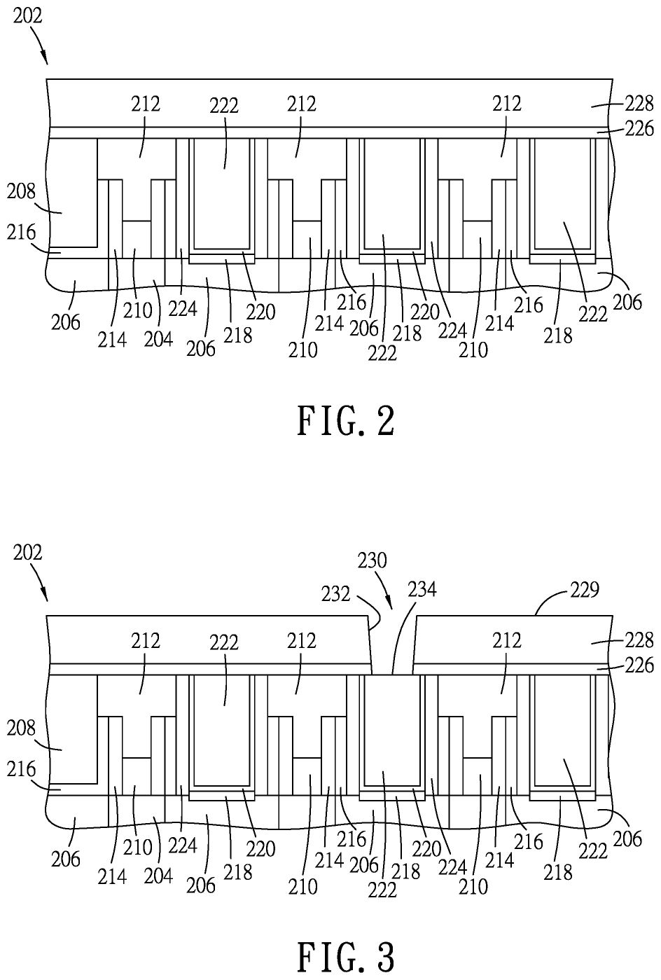

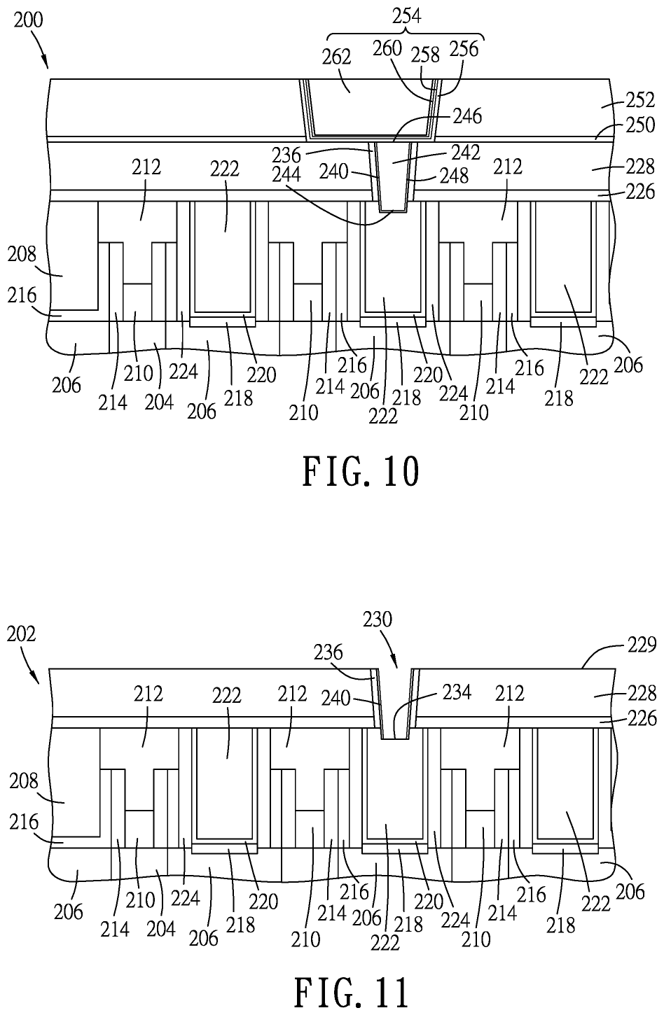

FIG. 1 illustrates a method 100 of forming a semiconductor device 200 (see FIG. 10) in accordance with some embodiments. FIGS. 2 to 6 and 8 to 10 are schematic views showing intermediate stages of the method 100 as depicted in FIG. 1. Additional steps which are not limited to those described in the method 100, can be provided before, after or during manufacturing of the semiconductor device 200, and some of the steps described herein may be replaced by other steps or be eliminated. Similarly, additional features may be present in the semiconductor device 200, and/or features present may be replaced or eliminated in additional embodiments.

Referring to FIG. 1, in a step 102 of the method 100, a semiconductor structure is formed. Referring to FIG. 2, in some embodiments, the semiconductor structure 202 includes a substrate 204, a plurality of source/drain regions 206 that are disposed in the substrate 204 and that are spaced apart from each other, a plurality of silicide structures 218 that are disposed on the source/drain regions 206, a first dielectric layer 208 that is disposed over the substrate 204, a plurality of conductive contacts 222 that are disposed in the first dielectric layer 208 and over the source/drain regions 206, a plurality of gate structures 210 that are disposed adjacent to the conductive contacts 222, a plurality of mask layers 212 that are disposed over the gate structures 210, a plurality of first gate spacers 214 and a plurality of second gate spacers 216 that are disposed adjacent to the gate structures 210, a plurality of contact spacers 224 that are disposed adjacent to the conductive contacts 222. In some embodiments, the semiconductor structure 202 further includes a middle contact etch stop layer 226 that is disposed over the first dielectric layer 208, and a second dielectric layer 228 that is disposed over the middle contact etch stop layer 226. In some embodiments, the second dielectric layer 228 has a dielectric surface 229 opposite to the first dielectric layer 208.

In some embodiments, the substrate 204 may include, for example, but not limited to, an elemental semiconductor or a compound semiconductor. The elemental semiconductor includes a single species of atoms, such as Si or Ge in column XIV of the periodic table, and may be crystalline, polycrystalline, or an amorphous structure. Other suitable materials are within the contemplated scope of the present disclosure. The compound semiconductor includes two or more elements, and examples thereof may include, but are not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable materials are within the contemplated scope of the present disclosure. The compound semiconductor may have a gradient feature in which the composition ratio thereof changes from one location to another location in the compound semiconductor. The compound semiconductor may be formed over a silicon substrate. The compound semiconductor may be strained. In some embodiments, the substrate 204 may include a multilayer compound semiconductor structure. In some embodiments, the substrate 204 may be a semiconductor-on-insulator (SOI) (e.g., silicon germanium-on-insulator (SGOI)). Generally, an SOI substrate includes a layer of a semiconductor material such as epitaxial silicon, germanium, silicon germanium, or any combination thereof. Other suitable materials are within the contemplated scope of the present disclosure. The SOI substrate may be doped with a P-type dopant, for example, but not limited to, boron (Br), aluminum (Al), or gallium (Ga). Other suitable materials are within the contemplated scope of the present disclosure. Alternatively, the SOI substrate may be doped with an N-type dopant, for example, but not limited to, nitrogen (N), phosphorous (P), or arsenic (As). Other suitable materials are within the contemplated scope of the present disclosure.

In some embodiments, the source/drain regions 206 may be formed by epitaxial growth techniques, other suitable techniques, or any combination thereof. In some embodiments, the source/drain regions 206 may be made of crystalline silicon (or other suitable semiconductor materials) doped with P-type dopants, so as to form P-type S/D regions for PMOS (P-type metal oxide semiconductor) transistors. In some embodiments, the P-type dopants may be boron, aluminum, gallium, indium, BF₂, other suitable materials, or any combination thereof. In some embodiments, the source/drain regions 206 may be made of crystalline silicon (or other suitable semiconductor materials) doped with N-type dopants, so as to form N-type S/D regions for NMOS (N-type metal oxide semiconductor) transistors. In some embodiments, the N-type dopants may be phosphorous, nitrogen, arsenic, antimony, other suitable materials, or any combination thereof. In some embodiments, each of the source/drain regions 206 may include one or multiple layers of semiconductor materials.

In some embodiments, the first dielectric layer 208 may include a dielectric material, such as silicon oxide, silicon nitride, silicon oxynitride, amorphous fluorinated carbon, fluorinated silica glass (FSG), carbon doped silicon oxide (e.g., SiCOH), polyimide, parylene, bis-benzocyclobutenes (BCB), other suitable materials, or any combination thereof. In some embodiments, the first dielectric layer 208 may be formed by chemical vapor deposition (CVD), physical vapor deposition (PVD), atomic layer deposition (ALD), other suitable techniques, or any combination thereof.

In some embodiments, the silicide structures 218 may be formed by a pre-silicidation implantation process in which implant regions are formed in the source/drain regions 206, followed by a silicidation process in which the implant regions are subjected to a silicidation process so as to form the silicide structures 218. In some embodiments during the pre-silicidation implantation process, dopants (e.g., metal dopants, etc.) are implanted in the source/drain regions 206. In some embodiments, the silicide structures 218 may include a metal silicide material, such as titanium silicide (TiₓSi_{y}), molybdenum silicide (MoₓSi_{y}), nickel silicide (NiₓSi_{y}), ruthenium silicide (RuₓSi_{y}), cobalt silicide (CoₓSi_{y}), tungsten silicide (WₓSi_{y}), europium silicide (EuₓSi_{y}), erbium silicide (ErₓSi_{y}), titanium germanosilicide (TiₓSi_{y}Ge_{z}), molybdenum germanosilicide (MoₓSi_{y}Ge_{z}), nickel germanosilicide (NiₓSi_{y}Ge_{z}), ruthenium germanosilicide (RuₓSi_{y}Ge_{z}), cobalt germanosilicide (CoₓSi_{y}Ge_{z}), tungsten germanosilicide (WₓSi_{y}Ge_{z}), europium germanosilicide (EuₓSi_{y}Ge_{z}), erbium germanosilicide (ErₓSi_{y}Ge_{z}), other suitable materials, or any combination thereof. In some embodiments, the metal silicide material may be subjected to a nitridation treatment to reduce oxidation thereof. For example, titanium silicide may be subjected to a nitridation treatment so as to form titanium silicon nitride (TiSiN), and nickel silicide may be subjected to a nitridation treatment so as to form nickel silicon nitride (NiSiN).

In some embodiments, the protective liners 220 may include a metal material (e.g., Ru, Co, Mo, W, Ni, Ir, Rh, Os, etc.), a nitride-based material (e.g., TiN, TaN, WN, MoN, etc.), other suitable materials, or any combination thereof. In some embodiments, the protective liners 220 may be formed by CVD, ALD, PVD, other suitable techniques, or any combination thereof. In some embodiments, the protective liners 220 may prevent or minimize oxidation of the underlying silicide structures 218.

In some embodiments, the conductive contacts 222 may include Mo, W, Ru, Co, Ni, Ir, Rh, Os, other suitable materials, or any combination thereof. In some embodiments, the conductive contacts 222 may be formed by PVD, plating (including electroplating, electroless plating, etc.), CVD, ALD, other suitable techniques, or any combination thereof. In some embodiments, each of the conductive contacts 222 may be referred to as MD (metal over diffusion).

In some embodiments, the contact spacers 224 may include silicon oxide, silicon nitride, silicon carbide, silicon oxycarbide, silicon oxynitride, silicon carbonitride, silicon oxycarbonitride, boron nitride, silicon boron nitride, other suitable materials, or any combination thereof. In some embodiments, the contact spacers 224 may be formed by CVD, ALD, PVD, other suitable techniques, or any combination thereof.

In some embodiments, each of the gate structures 210 may include a gate dielectric and a metal gate, where the gate dielectric may include metal oxides (where the metal may include Li, Be, Mg, Ca, Sr, Sc, Y, Zr, Hf, Al, La, Ce, Pr, Nd, Sm, Eu, Gd, Tb, Dy, Ho, Er, Tm, Yb, Lu, other suitable metals, or any combination thereof), metal nitrides, metal silicates, metal oxynitrides, metal aluminates, silicon oxide, silicon nitride, silicon oxynitride, other suitable materials, or any combination thereof, and the metal gate may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, other suitable materials, or any combination thereof. In some embodiments, the gate dielectric and the metal gate of each of the gate structures 210 may be formed by CVD, ALD, PVD, other suitable techniques, or any combination thereof.

In some embodiments, the mask layers 212 may include LaO, AlO, YO, TaCN, ZrSi, SiOCN, SiOC, SiCN, ZrN, ZrAlO, TiO, TaO, ZrO, HfO, SiN, HfSi, AlON, SiO, SiC, ZnO, other suitable materials, or any combination thereof. In some embodiments, the mask layers 212 may be formed by CVD, ALD, PVD, other suitable techniques, or any combination thereof. In some embodiments, each of the mask layers 212 may be referred to as self-aligned contact (SAC).

In some embodiments, the first and second gate spacers 214, 216 may include silicon oxide, silicon nitride, silicon carbide, silicon oxycarbide, silicon oxynitride, silicon carbonitride, silicon oxycarbonitride, other suitable materials, or any combination thereof. In some embodiments, the first and second gate spacers 214, 216 may be formed by CVD, ALD, PVD, other suitable techniques, or any combination thereof.

In some embodiments, the middle contact etch stop layer 226 may include LaO, AlO, YO, TaCN, ZrSi, SiOCN, SiOC, SiCN, ZrN, ZrAlO, TiO, TaO, ZrO, HfO, SiN, HfSi, AlON, SiO, SiC, ZnO, other suitable materials, or any combination thereof. In some embodiments, the middle contact etch stop layer 226 may be formed by CVD, ALD, PVD, other suitable techniques, or any combination thereof.

In some embodiments, the second dielectric layer 228 may include a dielectric material, such as silicon oxide, silicon nitride, silicon oxynitride, amorphous fluorinated carbon, FSG, carbon doped silicon oxide (e.g., SiCOH), polyimide, parylene, BCB, other suitable materials, or any combination thereof. In some embodiments, the second dielectric layer 228 may be formed by CVD, ALD, PVD, other suitable techniques, or any combination thereof.

Referring to FIG. 1, in a step 104 of the method 100, a contact opening is formed. Referring to FIG. 3, in some embodiments, the contact opening 230 may be formed in the second dielectric layer 228, and may terminate at the middle contact etch stop layer 226 or may penetrate the middle contact etch stop layer 226 to expose a conductive surface 234 of a corresponding one of the conductive contacts 222. In some embodiments, the contact opening 230 may be formed by dry etch, wet etch, other suitable techniques, or any combination thereof. In some embodiments, the contact opening 230 may be defined by an opening-defining surface 232 and the conductive surface 234 of the corresponding one of the conductive contacts 222, where the opening-defining surface 232 may be constituted by the middle contact etch stop layer 226 and the second dielectric layer 228. In some embodiments, the contact opening 230 may have a circular, oval, square, rectangular top shape, or may have other suitable top shapes.

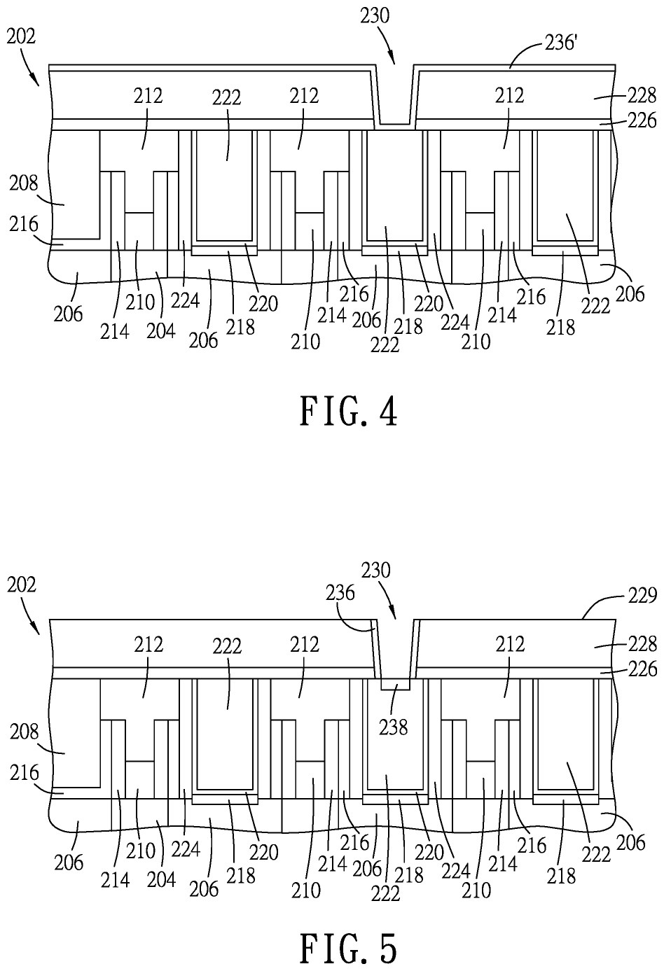

Referring to FIG. 1, in a step 106 of the method 100, a spacer is formed in the contact opening. Referring to FIGS. 3 and 4, in some embodiments, a spacer layer 236′ may be formed on the dielectric surface 229 of the second dielectric layer 228, on the opening-defining surface 232, and on the conductive surface 234 of the corresponding one of the conductive contacts 222. Then, referring to FIG. 5, a portion of the spacer layer 236′ may be removed, such as by directional dry etch, to form the spacer 236 in the contact opening 230. In some embodiments, the spacer layer 236′ (i.e., the spacer 236) may include silicon oxide, silicon nitride, silicon carbide, silicon oxycarbide, silicon oxynitride, silicon carbonitride, silicon oxycarbonitride, other suitable materials, or any combination thereof. In some embodiments, the spacer layer 236′ may be formed by CVD, PVD, ALD, other suitable techniques, or any combination thereof. In some embodiments, during the removal of the portion of the spacer layer 236′, the spacer layer 236′ on the dielectric surface 229 of the second dielectric layer 228 and on the conductive surface 234 of the corresponding one of the conductive contacts 222 is removed, while the spacer layer 236′ on the opening-defining surface 232 is not removed to form the spacer 236. In some embodiments, during the removal of the portion of the spacer layer 236′, the corresponding one of the conductive contacts 222 may be slightly etched. In some embodiments, after the removal of the portion of the spacer layer 236′, a residue 238 (see FIG. 5) may be formed on the conductive surface 234 of the corresponding one of the conductive contacts 222, and may include metal oxide, which may be a result of oxidation of the corresponding one of the conductive contacts 222.

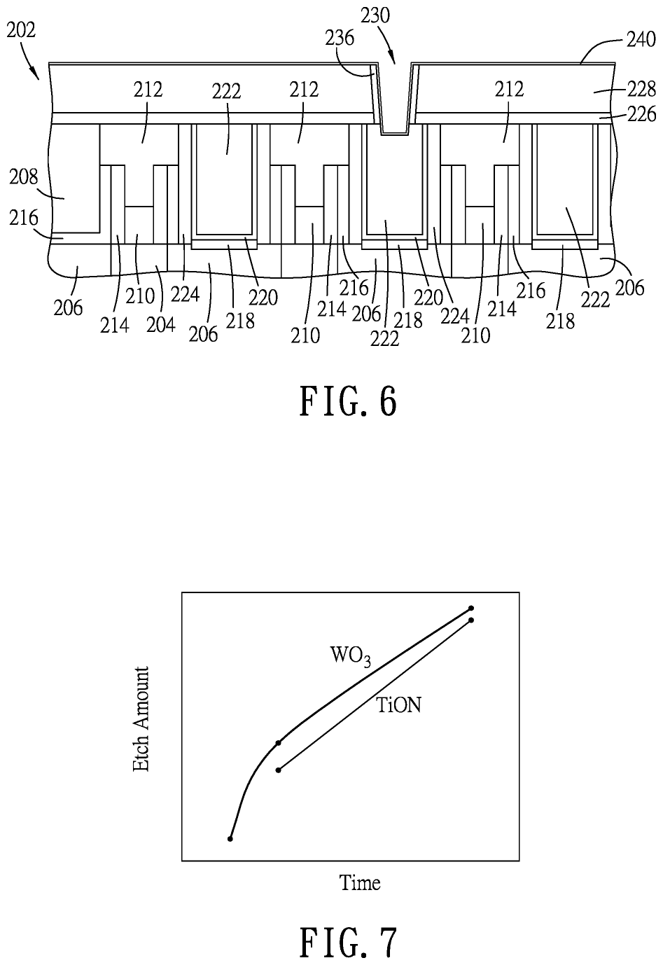

Referring to FIG. 1, in a step 108 of the method 100, the residue in the contact opening is removed. Referring to FIGS. 3, 5 and 6, in some embodiments, the residue 238 may be removed, such as by using a first metal halide for etching the residue 238. In some embodiments, the first metal halide may have a chemical formula of AₓB_{y}, where A may be W, Mo, Ru, Ti, other suitable materials, or any combination thereof, B may be F, Cl, I, other suitable materials, or any combination thereof, x may range from 1 to 2, and y may range from 1 to 10. In some embodiments, the first metal halide may include tungsten fluoride (including tungsten(IV) fluoride (WF₄), tungsten(VI) fluoride (WF₆), or the like), tungsten chloride (including tungsten(II) chloride (WCl₂), tungsten(III) chloride (WCl₃), tungsten(IV) chloride (WCl₄), tungsten(V) chloride (WCl₅), tungsten(VI) chloride (WCl₆), or the like), tungsten iodide (including tungsten(III) iodide (WI₃), or the like), molybdenum fluoride (including molybdenum(IV) fluoride (MoF₄), molybdenum(V) fluoride (MoF₅), molybdenum(VI) fluoride (MoF₆), or the like), molybdenum chloride (including molybdenum(II) chloride (MoCl₂), molybdenum(III) chloride (MoCl₃), molybdenum(IV) chloride (MoCl₄), molybdenum(V) chloride (MoCl₅ or Mo₂Cl₁₀), molybdenum(VI) chloride (MoCl₆), or the like), molybdenum iodide (including molybdenum(III) iodide (MoI₃), or the like), ruthenium fluoride (including ruthenium(V) fluoride (RuF₅ or Ru₂F₁₀), ruthenium(VI) fluoride (RuF₆), or the like), ruthenium chloride (including ruthenium(III) chloride (RuCl₃), or the like), ruthenium iodine (including ruthenium(III) iodine (RuI₃), or the like), titanium fluoride (including titanium(III) fluoride (TiF₃), titanium(IV) fluoride (TiF₄), or the like), titanium chloride (including titanium(II) chloride (TiCl₂), titanium(III) chloride (TiCl₃), titanium(IV) chloride (TiCl₄), or the like), titanium iodide (including titanium(IV) iodide (TiI₄), or the like), other suitable materials, or any combination thereof. As shown in FIG. 6, after the removal of the residue 238 (see FIG. 5), a metal (i.e., a first metal) 240 from the first metal halide may remain on the dielectric surface 229 of the second dielectric layer 228, on the spacer 236 which is formed on the opening-defining surface 232 (see FIG. 3), and on the conductive surface 234 of the corresponding one of the conductive contacts 222. In some embodiments, the first metal 240 may include W, Mo, Ru, Ti, other suitable metals, or any combination thereof. In some embodiments, although the first metal 240 is illustrated as a single layer in FIG. 6 and subsequent figures, the first metal 240 may be constituted by multiple metal particles.

FIG. 7 is a graph plot illustrating the etch amount versus time of WO₃ and TiON by using WF₆ as an etchant at certain temperatures. In some embodiments, WF₆ has an etch rate on WO₃ or TiON at about 0.5 Å/sec to about 1 Å/sec, at about 0.5 Å/sec to about 0.55 Å/sec, at about 0.55 Å/sec to about 0.6 Å/sec, at about 0.6 Å/sec to about 0.65 Å/sec, at about 0.65 Å/sec to about 0.7 Å/sec, at about 0.7 Å/sec to about 0.75 Å/sec, at about 0.75 Å/sec to about 0.8 Å/sec, at about 0.8 Å/sec to about 0.85 Å/sec, at about 0.85 Å/sec to about 0.9 Å/sec, at about 0.9 Å/sec to about 0.95 Å/sec, at about 0.95 Å/sec to about 1 Å/sec, or may be in other suitable ranges, depending on process parameters, such as temperature, concentration of metal halide, profile of contact opening, etc.

In some embodiments, after the removal of the portion of the spacer layer 236′ but prior to the removal of the residue 238 in the contact opening 230, an ash process (e.g., by using N₂, H₂, O₂ plasma, etc.) may be applied to the contact opening 230 for removing by-product as a result of the removal of the portion of the spacer layer 236′ (e.g., carbon-containing materials, fluorine-containing materials, etc.). In addition, in some embodiments, after the ash process but prior to the removal of the residue 238 in the contact opening 230, an etch process (e.g., by using a combination of HF and NH₃, a combination of NF₃ and NH₃, which may be in a form of plasma, etc.) may be used for removing silicon oxide in the contact opening 230. In some embodiments, silicon oxide may result from oxidation of the second dielectric layer 228 during the removal of the portion of the spacer layer 236′, the ash process, and/or other process steps.

In some embodiments, after the ash process, silicon oxide may be reduced into silicon or silane by hydrogen plasma or the like, followed by using the first metal halide to remove silicon or silane and the residue 238.

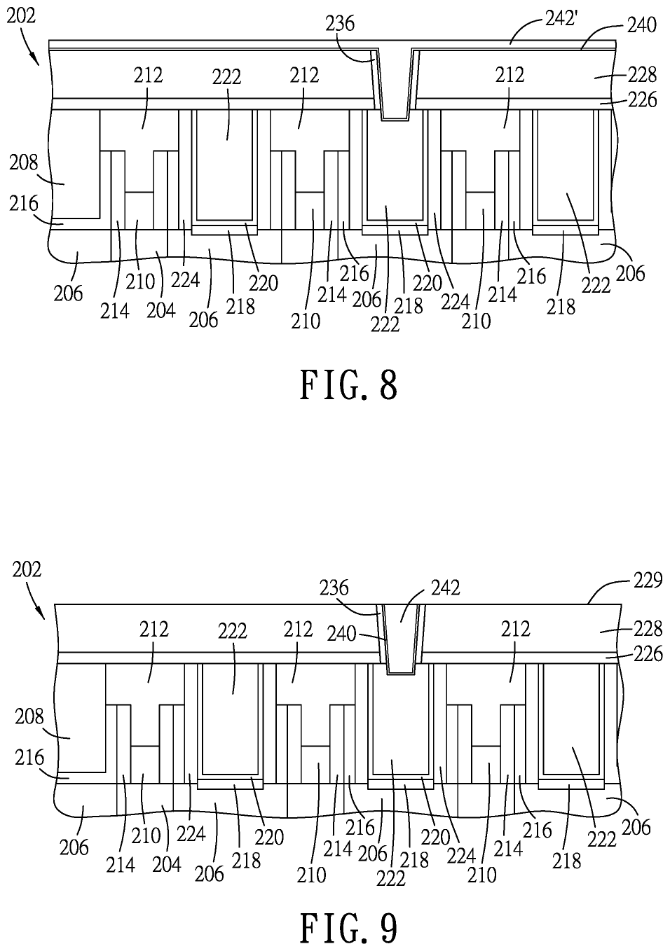

Referring to FIG. 1, in a step 110 of the method 100, a via contact is formed. Referring to FIG. 8, in some embodiments, a filling layer 242′ is formed over the dielectric surface 229 of the second dielectric layer 228 and fills the contact opening 230. Then, referring to FIGS. 8 and 9, a portion of the filling layer 242′ over the second dielectric layer 228 may be removed (e.g., by chemical mechanical planarization (CMP), dry etch, wet etch, other suitable techniques, or any combination thereof) to form the via contact 242. In some embodiments, the first metal 240 on the dielectric surface 229 of the second dielectric layer 228 may also be removed. In some embodiments, the filling layer 242′ (i.e., the via contact 242) may be made of Mo, W, Ru, Co, Ni, Ir, Rh, Os, other suitable materials, or any combination thereof, and may be made by PVD, plating (including electroplating, electroless plating, etc.), CVD, ALD, other suitable techniques, or any combination thereof. In some embodiments, the first metal 240 and the via contact 242 may be made of the same material or different materials.

Referring to FIG. 1, in a step 112 of the method 100, a conductive line is formed. Referring to FIG. 10, in some embodiments, an etch stop layer 250 may be formed over the second dielectric layer 228, followed by forming a third dielectric layer 252 over the etch stop layer 250. In some embodiments, the etch stop layer 250 may include LaO, AlO, YO, TaCN, ZrSi, SiOCN, SiOC, SiCN, ZrN, ZrAlO, TiO, TaO, ZrO, HfO, SiN, HfSi, AlON, SiO, SiC, ZnO, other suitable materials, or any combination thereof. In some embodiments, the etch stop layer 250 may be formed by CVD, ALD, PVD, other suitable techniques, or any combination thereof. In some embodiments, the third dielectric layer 252 may include a dielectric material, such as silicon oxide, silicon nitride, silicon oxynitride, amorphous fluorinated carbon, FSG, carbon doped silicon oxide (e.g., SiCOH), polyimide, parylene, BCB, other suitable materials, or any combination thereof. In some embodiments, the third dielectric layer 252 may be formed by CVD, ALD, PVD, other suitable techniques, or any combination thereof. Then the conductive line 254 may be formed in the etch stop layer 250 and the third dielectric layer 252, and may be connected to the via contact 242, thereby obtaining the semiconductor device 200. In some embodiments, the conductive line 254 may include a barrier layer 256, a first liner layer 258 covering the barrier layer 256, a second liner layer 260 covering the first liner layer 258, and a conductive layer 262 filled in a space defined by the second liner layer 260. In some embodiments, the barrier layer 256 may include Ti, Ta, TiN, TaN, other suitable materials, or any combination thereof. In some embodiments, each of the first and second liner layers 258, 260 may include Co, Ru, other suitable materials, or any combination thereof. In some embodiments, the conductive layer 262 may include Ag, Al, Cu, W, Ni, other suitable materials, or any combination thereof. In some embodiments, each of the barrier layer 256, the first liner layer 258 and the second liner layer 260 may be made by CVD, ALD, PVD, other suitable techniques, or any combination thereof. In some embodiments, the first metal 240 and the conductive line 254 (e.g., the conductive layer 262 of the conductive line 254) may be made of the same material or different materials.

Referring to FIG. 10, in some embodiments, the via contact 242 may have a first surface 244 that may be connected to the corresponding one of the conductive contacts 222, a second surface 246 that is opposite to the first surface 244 and that is connected to the conductive line 254, and a third surface 248 that is connected between the first and second surfaces 244, 246. In some embodiments, the first metal 240 may be connected to the first and third surfaces 244, 248, and may be disposed outside of the second surface 246. In some embodiments, halogen from the first metal halide may be present around the via contact 242, for example, present at the first and third surfaces 244, 248 of the via contact 242.

Referring to FIGS. 5, 6 and 11, in some embodiments, after the removal of the residue 238 which may include the removal of silicon oxide followed by removing the metal oxide or may include reducing silicon oxide into silicon or silane followed by removing silicon or silane and the metal oxide, the first metal 240 on the conductive surface 234 of the corresponding one of the conductive contacts 222 may be removed by plasma treatment with a plasma containing Ar, He, other suitable materials, or any combination thereof. In some embodiments, the first metal 240 on the dielectric surface 229 of the second dielectric layer 228 may also be removed by the plasma treatment. In some embodiments, the power for generating the plasma may be greater than about 0 W and not greater than about 1000 W, but other ranges of values are also within the scope of this disclosure. In some embodiments, if the power for generating the plasma is too large, such as greater than about 1000 W, the plasma may widen the contact opening 230 and/or damage the spacer 236. In some embodiments, the duration of plasma treatment may be greater than about 0 second and not greater than about 10 seconds. In some embodiments, if the duration of plasma treatment is too large, such as greater than about 10 seconds, the plasma may widen the contact opening 230 and/or damage the spacer 236. In some embodiments, the amount (e.g., thickness) of the second dielectric layer 228 being etched away by the plasma may be greater than about 0 nanometer and not greater than about 1 nanometer. In some embodiments, in cases where the amount (e.g., thickness) of the second dielectric layer 228 being etched away is too large, such as greater than about 1 nanometer, the power for generating the plasma and/or the duration of plasma etch is too large. Then, referring to FIG. 12, the etch stop layer 250 and the third dielectric layer 252 are formed over the second dielectric layer 228, followed by forming the conductive line 254 in the etch stop layer 250 and the third dielectric layer 252, thereby obtaining the semiconductor device 200, where the first metal 240 is formed on the third surface 248 of the via contact 242 outside of the first and second surfaces 244, 246 of the via contact 242.

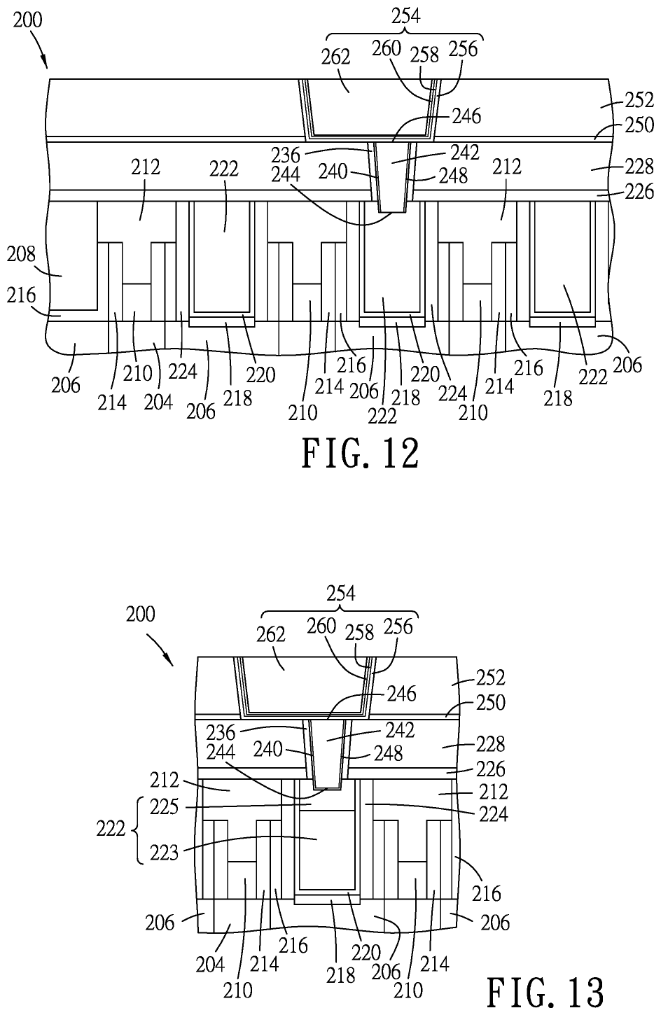

FIG. 13 is a schematic partial view of the semiconductor device 200 in accordance with some embodiments, where the conductive contact 222 in FIG. 13 includes a first contact structure 223 that is disposed over the silicide structure 218 and a second contact structure 225 that is disposed over the first contact structure 223, and the via contact 242 may be disposed over and connected to the second contact structure 225. In some embodiments, the first metal 240 may be disposed on the first and third surfaces 244, 248 of the via contact 242 and outside of the second surface 246 of the via contact 242; and, in other embodiments, the first metal 240 may be disposed on the third surface 248 of the via contact 242 and outside of the first and second surfaces 244, 246 of the via contact 242. In some embodiments, the second contact structure 225 may be made of a material that matches the material of the via contact 242, which leads to low resistivity between the second contact structure 225 and the via contact 242. For example, the second contact structure 225 and the via contact 242 may be made of the same material.

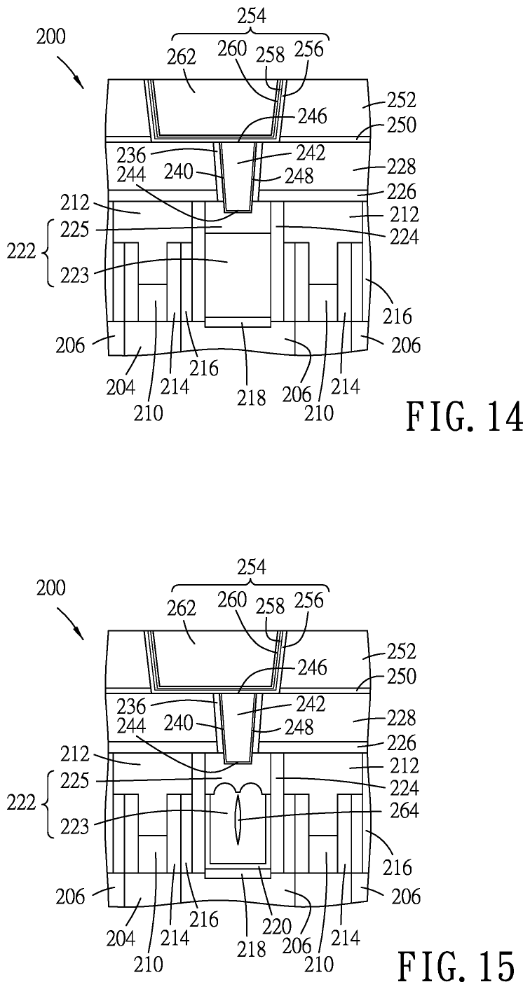

FIG. 14 is a schematic partial view similar to FIG. 13, but FIG. 14 shows that the protective liner 220 is omitted, in accordance with some embodiments. In FIG. 14, the first metal 240 is disposed on the first and third surfaces 244, 248 of the via contact 242 and outside of the second surface 246 of the via contact 242; but, in other embodiments, the first metal 240 may be disposed on the third surface 248 of the via contact 242 and outside of the first and second surfaces 244, 246 of the via contact 242.

FIG. 15 is a schematic partial view similar to FIG. 13, but FIG. 15 shows that the protective liner 220 is disposed below the second contact structure 225 of the conductive contact 222, and the first contact structure 223 may be formed by a selective deposition process (e.g., selective CVD, selective ALD, etc.), where the first contact structure 223 may be selectively formed on the protective liner 220. In some embodiments, the first contact structure 223 may slightly protrude beyond (i.e., protrude over) the protective liner 220. In some embodiments, the first contact structure 223 may be formed with a seam 264. In FIG. 15, the first metal 240 is disposed on the first and third surfaces 244, 248 of the via contact 242 and outside of the second surface 246 of the via contact 242; but, in other embodiments, the first metal 240 may be disposed on the third surface 248 of the via contact 242 and outside of the first and second surfaces 244, 246 of the via contact 242.

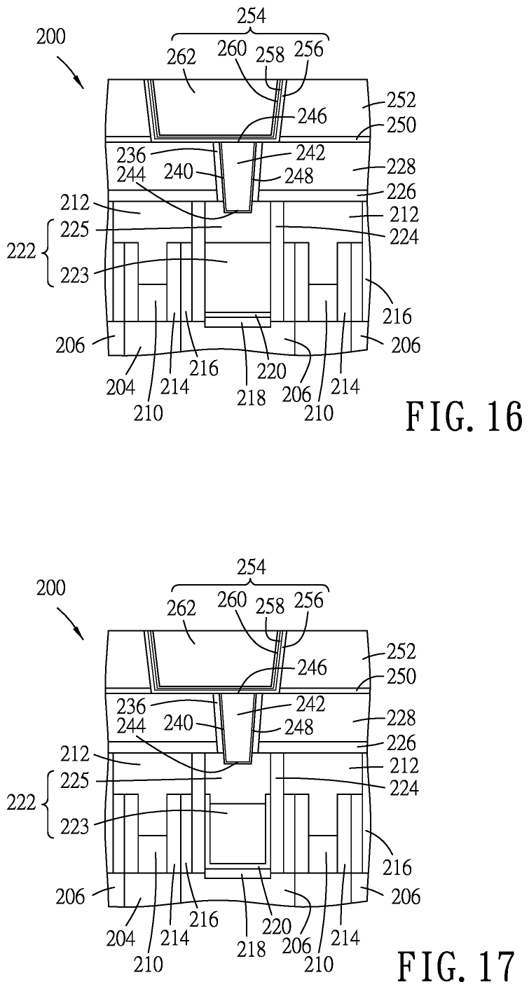

FIG. 16 is a schematic partial view similar to FIG. 13, but FIG. 16 shows that the conductive contact 222 is disposed over the protective liner 220. In FIG. 16, the first metal 240 is disposed on the first and third surfaces 244, 248 of the via contact 242 and outside of the second surface 246 of the via contact 242; but, in other embodiments, the first metal 240 may be disposed on the third surface 248 of the via contact 242 and outside of the first and second surfaces 244, 246 of the via contact 242.

FIG. 17 is a schematic partial view similar to FIG. 13, but FIG. 17 shows that the protective liner 220 is lower than the contact spacer 224, and the first contact structure 223 of the conductive contact 222 is lower than the protective liner 220. In FIG. 17, the first metal 240 is disposed on the first and third surfaces 244, 248 of the via contact 242 and outside of the second surface 246 of the via contact 242; but, in other embodiments, the first metal 240 may be disposed on the third surface 248 of the via contact 242 and outside of the first and second surfaces 244, 246 of the via contact 242.

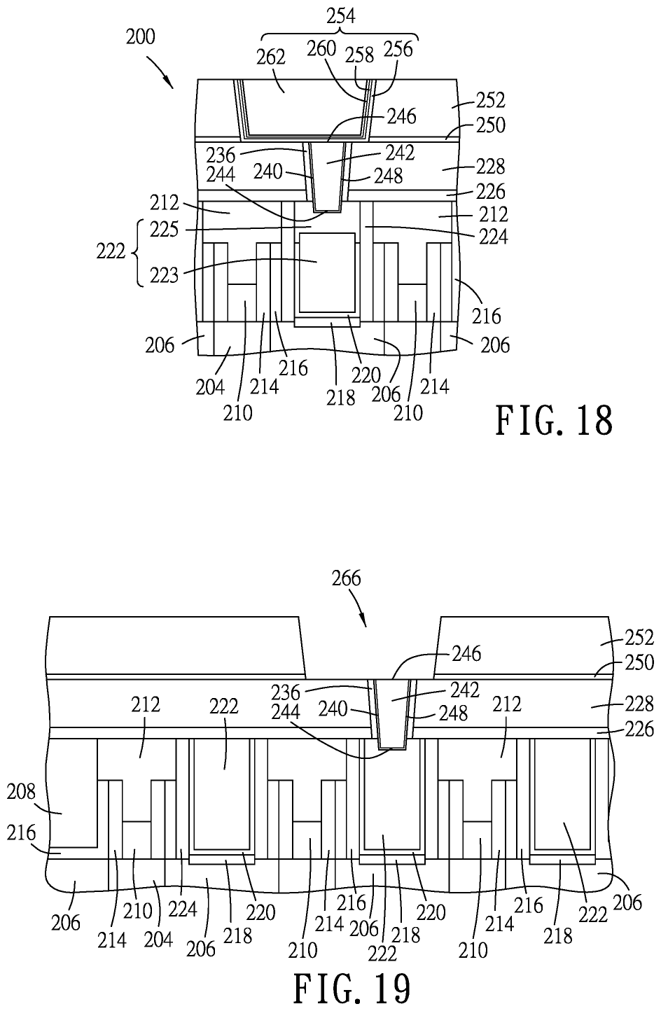

FIG. 18 is a schematic partial view similar to FIG. 17, but FIG. 18 shows that the first contact structure 223 slightly protrudes beyond (i.e., protrudes over) the protective liner 220. In FIG. 18, the first metal 240 is disposed on the first and third surfaces 244, 248 of the via contact 242 and outside of the second surface 246 of the via contact 242; but, in other embodiments, the first metal 240 may be disposed on the third surface 248 of the via contact 242 and outside of the first and second surfaces 244, 246 of the via contact 242.

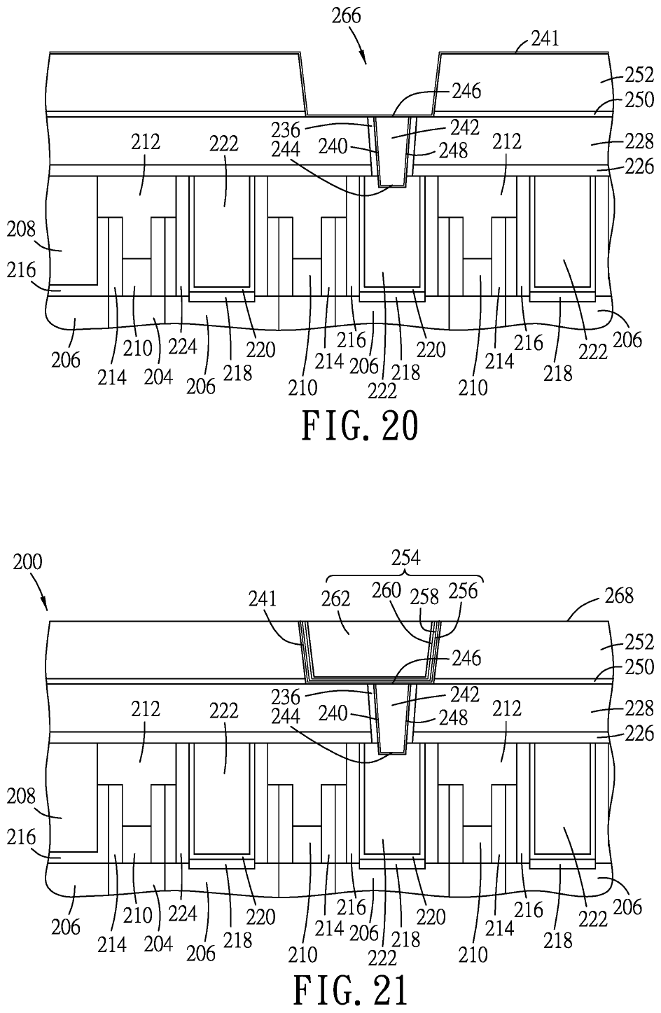

Referring to FIG. 19, in some embodiments after forming the third dielectric layer 252, a trench 266 may be formed in the third dielectric layer 252 and the etch stop layer 250 to expose the second surface 246 of the via contact 242. Referring to FIG. 20, in some embodiments, the second surface 246 of the via contact 242 may be treated with a second metal halide to remove metal oxide thereon. In some embodiments, the second metal halide may be the same or different from the abovementioned first metal halide. After the metal halide treatment, a second metal 241 from the second metal halide may be left on the third dielectric layer 252, the second dielectric layer 228, and the second surface 246 of the via contact 242. Referring to FIG. 21, in some embodiments, the conductive line 254 may be formed in the trench 266 to be connected to the via contact 242, where the first metal 240 is disposed on the first and third surfaces 244, 248 of the via contact 242, the second metal 241 is disposed on the second surface 246 of the via contact 242, and the conductive line 254 is surrounded by the second metal 241. In some embodiments, the second metal 241 on a surface 268 (e.g., a top surface) of the third dielectric layer 252 may be removed during the formation of the conductive line 254. In some embodiments, the first metal 240 and the second metal 241 may be the same or different from each other, depending on the metal halide(s) used.

The embodiments of the present disclosure have some advantageous features. In some embodiments, metal oxide on the conductive contact 222 may be removed by using dry etch techniques, such as Ar plasma etching. However, in some embodiments, the dry etch techniques may widen the contact opening 230 and/or form a necking profile in the contact opening 230. B_{y} using metal halide, which may readily etch metal oxide and not etch or only slightly etch other materials, such as silicon-oxide-based and/or silicon-nitride-based materials, the metal oxide can be removed without substantially changing the dimension and/or profile of the contact opening 230. After the metal halide etching process, metal from the metal halide may be formed in the contact opening 230, and may be detectable by suitable pieces of apparatus.

In accordance with some embodiments of the present disclosure, a semiconductor device includes a substrate, a source/drain region disposed in the substrate, a silicide structure disposed on the source/drain region, a first dielectric layer disposed over the substrate, a conductive contact disposed in the first dielectric layer and over the silicide structure, a second dielectric layer disposed over the first dielectric layer, a via contact disposed in the second dielectric layer and connected to the conductive contact, and a first metal surrounding the via contact.

In accordance with some embodiments of the present disclosure, the first metal includes W, Mo, Ru, or Ti.

In accordance with some embodiments of the present disclosure, the first metal and the conductive contact are made of different materials.

In accordance with some embodiments of the present disclosure, the via contact has a first surface connected to the conductive contact, a second surface opposite to the first surface, and a third surface connected between the first and second surfaces. The first metal id disposed on the third surface of the via contact.

In accordance with some embodiments of the present disclosure, the first metal is further disposed on the first surface of the via contact.

In accordance with some embodiments of the present disclosure, the semiconductor device further includes a second metal that is disposed on the second surface of the via contact.

In accordance with some embodiments of the present disclosure, the semiconductor device further includes a spacer that is disposed between the second dielectric layer and the via contact. The first metal is disposed between the spacer and the via contact.

In accordance with some embodiments of the present disclosure, a semiconductor device includes a substrate, a source/drain region disposed in the substrate, a silicide structure disposed on the source/drain region, a first dielectric layer disposed over the substrate, a conductive contact disposed in the first dielectric layer and over the silicide structure, a second dielectric layer disposed over the first dielectric layer, a via contact disposed in the second dielectric layer and connected to the conductive contact, a third dielectric layer disposed over the second dielectric layer, a conductive line disposed in the third dielectric layer and connected to the via contact, and a first metal disposed around the via contact and disposed between the conductive contact and the conductive line.

In accordance with some embodiments of the present disclosure, the first metal includes W, Mo, Ru, or Ti.

In accordance with some embodiments of the present disclosure, the first metal and the conductive contact are made of different materials, and the first metal and the conductive line are made of different materials.

In accordance with some embodiments of the present disclosure, the via contact has a first surface connected to the conductive contact, a second surface opposite to the first surface and connected to the conductive line, and a third surface connected between the first and second surfaces. The first metal is disposed on the third surface of the via contact.

In accordance with some embodiments of the present disclosure, the first metal is further disposed on the first surface of the via contact.

In accordance with some embodiments of the present disclosure, the semiconductor device further includes a second metal that is disposed on the second surface of the via contact and around the conductive line.

In accordance with some embodiments of the present disclosure, the semiconductor device further includes a spacer that is disposed between the conductive contact and the conductive line, and that surrounds the via contact. The first metal is disposed between the spacer and the via contact.

In accordance with some embodiments of the present disclosure, a method for forming a semiconductor device includes: forming a semiconductor structure including a substrate, a source/drain region disposed in the substrate, a silicide structure disposed on the source/drain region, a first dielectric layer disposed over the substrate, a conductive contact disposed in the first dielectric layer and over the silicide structure, and a second dielectric layer disposed over the first dielectric layer; forming a contact opening in the second dielectric layer, the conductive contact having a conductive surface exposed from the contact opening, a residue being formed on the conductive surface and including metal oxide, the second dielectric layer having an opening-defining surface that cooperates with the conductive surface of the conductive contact to define the contact opening; removing the residue by using a first metal halide, a first metal of the first metal halide being formed on the opening-defining surface of the second dielectric layer and the conductive surface of the conductive contact; and forming a via contact in the contact opening.

In accordance with some embodiments of the present disclosure, the method further includes, prior to forming the via contact, removing the first metal on the conductive surface of the conductive contact.

In accordance with some embodiments of the present disclosure, in removing the residue, the first metal halide is used to etch away the residue. The first metal halide has a chemical formula of AₓB_{y}, where A includes W, Mo, Ru, or Ti, and B includes F, Cl, or I.

In accordance with some embodiments of the present disclosure, in removing the residue, the first metal is further formed over the second dielectric layer. In forming the via contact, a filling layer is formed in the contact opening and over the second dielectric layer, followed by removing a portion of the filling layer over the second dielectric layer and the first metal over the second dielectric layer.

In accordance with some embodiments of the present disclosure, the method further includes: forming a third dielectric layer over the second dielectric layer; forming a trench in the third dielectric layer, the via contact having a first surface connected to the conductive contact, and a second surface opposite to the first surface and exposed from the trench; applying a second metal halide to the third dielectric layer and the second surface of the via contact, a second metal of the second metal halide being formed on the second surface of the via contact and in the trench (266); and forming a conductive line in the trench.

In accordance with some embodiments of the present disclosure, the method further includes, after forming the contact opening and prior to removing the residue, forming a spacer in the contact opening, where, in removing the residue, the first metal is formed on the spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a source/drain region disposed in the substrate;
a silicide structure disposed on the source/drain region;
a first dielectric layer disposed over the substrate;
a conductive contact disposed in the first dielectric layer and over the silicide structure;
a second dielectric layer disposed over the first dielectric layer;
a via contact disposed in the second dielectric layer and connected to the conductive contact; and
a first metal surrounding the via contact.

2. The semiconductor device as claimed in claim 1, wherein the first metal includes W, Mo, Ru, or Ti.

3. The semiconductor device as claimed in claim 2, wherein the first metal and the conductive contact are made of different materials.

4. The semiconductor device as claimed in claim 1, wherein:
the via contact has a first surface connected to the conductive contact, a second surface opposite to the first surface, and a third surface connected between the first and second surfaces; and
the first metal is disposed on the third surface of the via contact.

5. The semiconductor device as claimed in claim 4, wherein the first metal is further disposed on the first surface of the via contact.

6. The semiconductor device as claimed in claim 5, further comprising a second metal that is disposed on the second surface of the via contact.

7. The semiconductor device as claimed in claim 1, further comprising a spacer that is disposed between the second dielectric layer and the via contact, the first metal being disposed between the spacer and the via contact.

8. A semiconductor device comprising:
a substrate;
a source/drain region disposed in the substrate;
a silicide structure disposed on the source/drain region;
a first dielectric layer disposed over the substrate;
a conductive contact disposed in the first dielectric layer and over the silicide structure;
a second dielectric layer disposed over the first dielectric layer;
a via contact disposed in the second dielectric layer and connected to the conductive contact;
a third dielectric layer disposed over the second dielectric layer;
a conductive line disposed in the third dielectric layer and connected to the via contact; and
a first metal disposed around the via contact and disposed between the conductive contact and the conductive line.

9. The semiconductor device as claimed in claim 8, wherein the first metal includes W, Mo, Ru, or Ti.

10. The semiconductor device as claimed in claim 9, wherein the first metal and the conductive contact are made of different materials, and the first metal and the conductive line are made of different materials.

11. The semiconductor device as claimed in claim 8, wherein:
the via contact has a first surface connected to the conductive contact, a second surface opposite to the first surface and connected to the conductive line, and a third surface connected between the first and second surfaces; and
the first metal is disposed on the third surface of the via contact.

12. The semiconductor device as claimed in claim 11, wherein the first metal is further disposed on the first surface of the via contact.

13. The semiconductor device as claimed in claim 12, further comprising a second metal that is disposed on the second surface of the via contact and around the conductive line.

14. The semiconductor device as claimed in claim 8, further comprising a spacer that is disposed between the conductive contact and the conductive line and that surrounds the via contact, the first metal being disposed between the spacer and the via contact.

15. A method for forming a semiconductor device, comprising:
forming a semiconductor structure including a substrate, a source/drain region disposed in the substrate, a silicide structure disposed on the source/drain region, a first dielectric layer disposed over the substrate, a conductive contact disposed in the first dielectric layer and over the silicide structure, and a second dielectric layer disposed over the first dielectric layer;
forming a contact opening in the second dielectric layer, the conductive contact having a conductive surface exposed from the contact opening, a residue being formed on the conductive surface and including metal oxide, the second dielectric layer having an opening-defining surface that cooperates with the conductive surface of the conductive contact to define the contact opening;
removing the residue by using a first metal halide, a first metal of the first metal halide being formed on the opening-defining surface of the second dielectric layer and the conductive surface of the conductive contact; and
forming a via contact in the contact opening.

16. The method as claimed in claim 15, further comprising, prior to forming the via contact, removing the first metal on the conductive surface of the conductive contact.

17. The method as claimed in claim 15, wherein, in removing the residue, the first metal halide is used to etch away the residue, the first metal halide having a chemical formula of AₓB_{y}, where A includes W, Mo, Ru, or Ti, and B includes F, Cl, or I.

18. The method as claimed in claim 15, wherein:
in removing the residue, the first metal being further formed over the second dielectric layer; and
in forming the via contact, a filling layer is formed in the contact opening and over the second dielectric layer, followed by removing a portion of the filling layer over the second dielectric layer and the first metal over the second dielectric layer.

19. The method as claimed in claim 15, further comprising:
forming a third dielectric layer over the second dielectric layer;
forming a trench in the third dielectric layer, the via contact having a first surface connected to the conductive contact, and a second surface opposite to the first surface and exposed from the trench;
applying a second metal halide to the third dielectric layer and the second surface of the via contact, a second metal of the second metal halide being formed on the second surface of the via contact and in the trench; and
forming a conductive line in the trench.

20. The method as claimed in claim 15, further comprising, after forming the contact opening and prior to removing the residue, forming a spacer in the contact opening (230), where, in removing the residue, the first metal is formed on the spacer.
